(19) United States
(12) Patent Application Publication
(10) Pub. No.: US 2013/0156950 A1
(43) Pub. Date: Jun. 20, 2013

(54) FILM-FORMING APPARATUS AND FILM-FORMING METHOD

(71) Applicant: NuFlare Technology, Inc., Numazu-shi (JP)

(72) Inventors: Takumi Yamada, Shizuoka (JP); Yuusuke Sato, Tokyo (JP)

(73) Assignee: NUFLARE TECHNOLOGY, INC, Numazu-shi (JP)

(21) Appl. No.: 13/713,326

(22) Filed: Dec. 13, 2012

(30) Foreign Application Priority Data
Dec. 14, 2011 (JP) 2011-273033

(51) Int. Cl. C23C 16/02

(52) U.S. Cl. CPC C23C 16/0236
USPC 427/248.1; 118/715; 118/696

(57) ABSTRACT

A film-forming apparatus 1 includes a reaction chamber 2, an exhaust mechanism 3, and a pipe 4 connecting them. An inert gas supply pipe 11 supplying an inert gas 15 in the pipe 4, and a trap section 5′ connecting with an exhaust pipe 16 exhausting a reaction product 14 are provided in the pipe 4. A substrate is disposed in the reaction chamber 2 and film formation is performed on the substrate by supplying a reaction gas 7 from a reaction gas supply pipe 8. The reaction product 14 is collected in the trap section 5′. An inert gas 15 is supplied to the trap section 5′ to pressure-feed the reaction product 14 from the exhaust pipe 16 to a detoxifying apparatus 20. Cleaning is performed by supplying a cleaning gas 21 to the reaction chamber 2 and exhausting the same while bypassing the trap section 5.

### CROSS-REFERENCE TO THE RELATED APPLICATION

The entire disclosure of the Japanese Patent Applications No. 2011-273033, filed on Dec. 14, 2011 including specification, claims, drawings, and summary, on which the Convention priority of the present application is based, are incorporated herein in its entirety.

### FIELD OF THE INVENTION

The present invention relates to a film-forming apparatus and a film-forming method.

### BACKGROUND ART

Epitaxial growth technique for used depositing a monocrystalline film on a substrate such as a wafer is conventionally used to produce a semiconductor device such as a power device (e.g., IGBT (Insulated Gate Bipolar Transistor)) requiring a relatively thick crystalline film.

In the case of film-forming apparatus used in an epitaxial growth technique, a wafer is placed inside a reaction chamber maintained at an atmospheric pressure or a reduced pressure, and a reaction gas is supplied into the reaction chamber while the wafer is heated. When a silicon (Si) film is formed on the substrate, a mixed gas comprising monosilane and hydrogen can be used as reaction gas (as described in Japanese Patent Application Laid-Open No. Hei 09-17734), dichlorosilane, trichlorosilane etc. can also be used. As a result, a pyrolytic reaction or a hydrogen reduction reaction of the reaction gas occurs on the surface of the wafer causing an epitaxial film to be formed on the wafer.

The gas generated by the reaction, as well as the gas not used in the reaction process is exhausted as a discharge gas out of the reaction chamber by an exhaust mechanism connected the reaction chamber. After the epitaxial film is formed on the wafer, the wafer is carried out from the reaction chamber. Another wafer is then carried into the reaction chamber, and then an epitaxial film will be formed on that wafer.

After the vapor-phase growth has been performed on the substrate, an unreacted component of a gas which has not been used for the vapor-growth reaction, an unstable intermediate component produced by the chemical reaction during film formation, and the like are included in an exhaust gas exhausted from the reaction chamber, as described above. These components cause an oily reaction product to gradually deposit on an inner face of a pipe connecting the reaction chamber and an exhaust mechanism. As the oily reaction product, an oily silane or the like is known, for example, such as reaction product described in Japanese Patent Application Laid-Open No. 2000-173925. The oily silane is a polymer material of silane chloride having a relatively high molecular weight, for example, a mixed material such as polychlorinated silane or polychlorinated siloxane. The oily silane has high viscosity and ignition quality, and a removal treatment thereof involves a risk and complexity.

Further, such a case may occur that a sectional area of a space inside a pipe connecting the reaction chamber and the exhaust mechanism is reduced by deposition of the reaction product of the oily silane or the like. There is a possibility that when the sectional area of the space inside the pipe becomes small, smooth exhaust of the exhaust gas from the reaction chamber is blocked so that a flow rate of a reactive gas within the reaction chamber fluctuates. The fluctuation of the flow rate of the reactive gas affects a pressure or a degree of vacuum, thereby causing destabilization of the film-forming conditions of the vapor-phase growth film. As a result, there is such a case that the film thickness or the performance of the vapor-phase growth film formed on the substrate is made uneven and lowering of the quality of the vapor-phase growth film is caused.

Therefore, consideration about providing a trap means for collecting the reaction product in the middle of the pipe connecting the reaction chamber and the exhaust mechanism has been made. When the trap means is provided, the reaction product corrected in the trap means is generally subjected to a manually-discarding treatment. For example, the trap means is detached from the pipe and the reaction product corrected therein is treated so as to be discarded manually.

As described above, however, the reaction product to be captured is oily silane or the like, the oily silane or the like has high viscosity and ignition quality, and a discarding work thereof involves complexity and risk. Therefore, a trap means where the reaction product collected in the trap means can be easily treated for discarding and the treating work can be safely performed has been demanded.

Further, in a film-forming apparatus which forms an epitaxial film on a substrate within a reaction chamber, cleaning to the inside of the apparatus using a cleaning gas containing chlorine trifluoride (ClF₃) is performed.

The cleaning gas has a function to react with the reaction product such as the above-described oily silane to decompose the same. By supplying the cleaning gas into the reaction chamber, the reaction product which has been attached to inside of the reaction chamber or the inside of the pipe connecting the reaction chamber and the exhaust mechanism can be removed. By such a cleaning work using the cleaning gas, the flow rate of the reactive gas within the reaction chamber is kept constant. The pressure or the degree of vacuum within the reaction chamber is maintained in a desired state, so that the film-forming conditions of the vapor-phase growth film can be stabilized.

Such a cleaning work is effective as a removing method thereof when a small amount of reaction product have been attached to the inside of the reaction chamber or the inside of the pipe connecting the reaction chamber to the exhaust mechanism. However, when a large amount of reaction product exists, it is difficult to remove the reaction product entirely. As described above, especially, there is such a case that the trap means is provided in the middle of the pipe connecting an exhaust port of the reaction chamber and the exhaust mechanism and the reaction product is collected therein. In such a case, it is difficult to completely remove the reaction product collected in the trap means by causing the cleaning gas to flow in the trap means.

Further, when the cleaning gas and the reaction product come in contact with each other in the trap means where the reaction product has accumulated, explosive severe reaction occurs between them. As a result, a risky situation such as heat generation may occur. Therefore, when the trap means is provided in the middle of the pipe connecting the reaction chamber and the exhaust mechanism, it is required to perform cleaning safely without introducing a cleaning gas containing ClF₃ into the trap means.

The present invention has been made in view of such a problem. That is, an object of the present invention is to provide a film-forming apparatus and a film-forming method where removal of a reaction product generated can be performed simply and safely.

Other challenges and advantages of the present invention are apparent from the following description.

### SUMMARY OF THE INVENTION

According to one aspect of the present invention, a film-forming apparatus comprises a reaction chamber having a reaction gas supply section, which supplies a reaction gas, for performing film formation on a substrate according to a vapor-phase growth reaction, a trap section capturing a reaction product resulting from the vapor-phase growth reaction in an exhaust gas exhausted from the reaction chamber, an exhaust mechanism exhausting the exhaust gas except for the captured reaction product in the trap section to the outside, and an inert gas supply section supplying an inert gas into the trap section in order to pressure-feed the captured reaction product to the outside of the trap section.

According to another aspect of the present invention, in a film-forming method, a substrate is provided in a reaction chamber and a reaction gas is supplied into the reaction chamber to perform film formation on the substrate according to a vapor-phase growth reaction, an exhaust gas exhausted from the reaction chamber is introduced into a trap section, capturing a reaction product contained in the exhaust gas, and exhausting the exhaust gas except for the captured reaction product; and inert gas is supplied into the trap section to pressure-feed the reaction product captured to the outside of the trap section.

### BRIEF DESCRIPTION OF THE DIAGRAMS

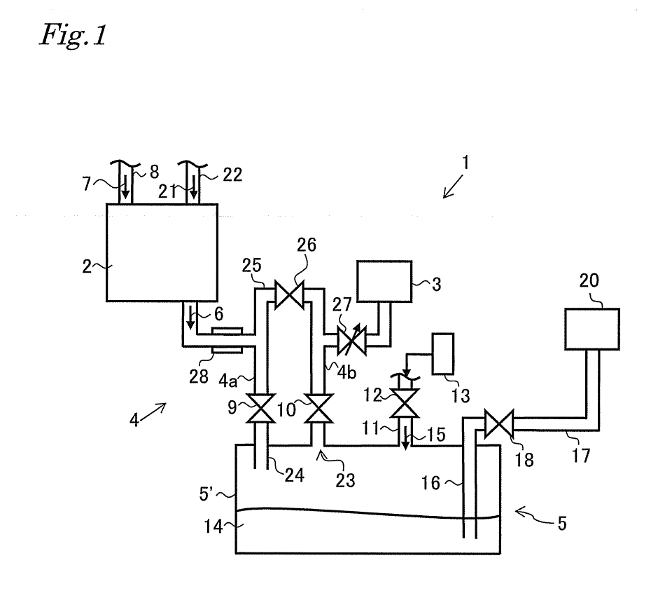

FIG. 1 is a schematic diagram for explaining a configuration of a main section of a film-forming apparatus of the first embodiment of the present invention.

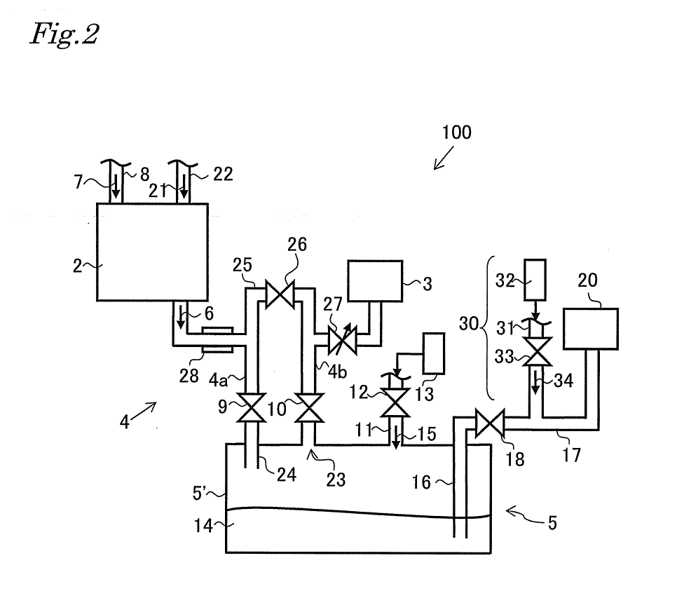

FIG. 2 is a schematic diagram for explaining a configuration of a main section of a film-forming apparatus of the second embodiment of the present invention.

### DETAILED DESCRIPTION OF INVENTION

### Embodiment 1

The description of a film-forming apparatus according to the first embodiment of the present invention will be described using FIG. 1.

FIG. 1 is a schematic diagram for explaining a configuration of a main section of a film-forming apparatus of the first embodiment of the present invention.

A film-forming apparatus 1 of this embodiment shown in FIG. 1 is provided with a reaction chamber 2, an exhaust mechanism 3, and a pipe 4 connecting the reaction chamber 2 and the exhaust mechanism 3 in a gas-piping fashion. A trap section 5′ is provided in the middle of the pipe 4 connecting the reaction chamber 2 and the exhaust mechanism 3, as described later.

A reaction gas supply pipe 8 which supplies a reaction gas 7 into the reaction chamber 2 is provided at a top portion of the reaction chamber 2. The reaction gas 7 is a gas containing a raw material gas used for film formation of a vapor-phase growth film, a hydrogen gas which is a carrier gas, and the like. The inside of the reaction chamber 2 is maintained in a predetermined degree of vacuum or a normal pressure (0.1 MPa (760 Torr)), and a predetermined vapor-phase growth film is formed by contacting of the reaction gas 7 with a substrate (not shown) which is heated and rotated within the reaction chamber 2.

As the raw material gas contained in the reaction gas 7, there are monosilane, dichlorosilane, trichlorosilane, and the like.

A gas containing a reaction product is exhausted from the inside of the reaction chamber 2 in which the film formation of the vapor-phase growth film is performed by the exhaust mechanism 3. The reaction product is a product which has been produced when the reaction gas 7 reacts in a thermally-decomposing manner or reacts in a hydrogen-reducing manner to react in a vapor-phase growing manner on a surface of the substrate. The exhaust mechanism 3 may be configured using, for example, a vacuum pump. At this time, an unreacted reaction gas which is not involved in film formation of the vapor-phase growth film directly and whose components doe not change chemically is also exhausted from the reaction chamber 2 in a state where the unreacted reaction gas has been mixed with the above-described gas. These gases exhausted from the reaction chamber 2 are hereinafter called “exhaust gas 6”. The above-described reaction product and components constituting the raw materials for the vapor-phase growth film are contained in the exhaust gas 6.

The exhaust gas 6 after the film formation of the vapor-phase growth film contains the above-described reaction product and the like, and it is exhausted from the reaction chamber 2 by the exhaust mechanism 3 connected to the reaction chamber 2 by the pipe 4. The film-forming apparatus 1 of this embodiment is provided with a trap apparatus 5 disposed in the middle of the pipe 4.

The trap apparatus 5 has a trap section 5′, and an exhaust gas introducing port 24 connected to a pipe 4a from the reaction chamber 2 and an exhaust gas exhausting port 23 connected to a pipe 4b communicating with the exhaust mechanism 3, both the exhaust gas introducing port 24 and the exhaust gas exhausting port 23 being provided in a top portion of the trap section 5′. An opening and closing valve 9 is provided in the pipe 4a between the reaction chamber 2 and the exhaust gas introducing port 24. On the other hand, an opening and closing valve 10 is provided in the pipe 4b between the exhaust mechanism 3 and the exhaust gas exhausting port 23.

The exhaust gas 6 exhausted from the reaction chamber 2 is introduced from the exhaust gas introducing port 24 into the trap section 5′ through the pipe 4a. The exhaust gas 6 is exhausted from the exhaust gas exhausting port 23 through the pipe 4b. At this time, the exhaust gas 6 which has been introduced into the trap section 5′ is cooled and the reaction product contained in the exhaust gas 6 is captured by the trap section 5′. The reaction product captured in the trap apparatus 5 changes into an oily reaction product 14 to accumulate on a bottom of the trap section 5′.

Here, in the film-forming apparatus 1, a cooling apparatus can be provided in the pipe 4a between the reaction chamber 2 and the opening and closing valve 9 or in the trap apparatus 5. In FIG. 1, an example where a flow passage 28 for cooling water surrounding the pipe 4a is provided, as the cooling apparatus, in the pipe 4a between the reaction chamber 2 and the opening and closing valve 9 is shown. Though not illustrated in FIG. 1, it is possible to provide a flow passage for cooling water so as to surround the trap section 5′ to configure the cooling apparatus. By providing such a cooling apparatus, the film-forming apparatus 1 can realize efficient cooling of the exhaust gas 6 from the reaction chamber 2 and can collect the reaction product 14 in the trap apparatus 5 efficiently.

Since the reaction product 14 contains oily silane or the like such as described above, it is rich in reactivity and has ignition quality. Therefore, there is a possibility that when the reaction product 14 which has accumulated on the bottom of the trap section 5′ is exposed to air, it is exploded, and a discarding treatment performed by a manual working under the atmosphere is a much risky working. Therefore, realization of a safe discarding treatment work performed automatically without depending on a manual work has been demanded.

As shown in FIG. 1, the trap apparatus 5 has an inert gas supply pipe 11 for supplying an inert gas 15 into the trap apparatus 5 at a top portion thereof. The inert gas supply pipe 11 is connected to an inert gas supply cylinder 13 which is an inert gas supply section via an opening and closing valve 12 in a gas-piping fashion.

It is preferred that a gas which does not react with the reaction product 14 within the trap apparatus 5 is selected and used as the inert gas 15. For example, besides a nitrogen gas, a helium (He) gas, a neon (Ne) gas, an argon (Ar) gas, or the like can be selected and used.

The trap apparatus 5 has an exhaust pipe 16 provided so as to extend from a top portion thereof toward a bottom thereof. The exhaust pipe 16 is connected to a pipe 17 at a top portion of the trap apparatus 5. An opening and closing valve 18 is provided in the pipe 17.

Therefore, when the oily reaction product 14 has accumulated in the trap section 5′, the opening and closing valves 9 and 10 in the pipe 4a and the pipe 4b described above are closed, respectively, and the inert gas 15 can then be introduced into the trap section 5′ by opening the opening and closing valves 12 and 18, respectively. The reaction product 14 can be pressure-fed from the exhaust pipe 16 to the outside of the trap section 5′ by a supplying pressure of the inert gas 15 supplied to the inside of the trap section 5′.

At this time, it is possible to set the internal capacity of the trap section 5′ to 3 liters to 10 liters, and it is also possible to set the flow rate of the inert gas 15 to 1 liter/min. to 3 liters/min. and set the supplying pressure to 100 kPa to 300 kPa. Incidentally, it is preferred that the supplying pressure of the inert gas 15 is adjusted according to the distance between the exhaust pipe 16 and a discarding system described later, and it is also preferred that a higher supplying pressure of the inert gas 15 is selected according to increase of the distance from the exhaust pipe 16 to the discarding system.

The film-forming apparatus 1 of this embodiment can have the discarding system which can make automatic and safe discarding treatment to the reaction product 14 possible without depending on manual work. It is preferred that such a discarding system is provided at a distal end of the pipe 17 connected to the pipe 16. As the discarding system, it is preferred that a sealing container which can be sealed and can discard the reaction product without exposing the reaction product to the atmosphere or a detoxifying apparatus which can detoxify the reaction product to discard the same is used.

The film-forming apparatus 1 of this embodiment shown in FIG. 1 has a detoxifying apparatus 20 which can detoxify the exhaust gas 16 and the reaction product 14 to discard them as the discarding system for the reaction product 14. In the trap apparatus 5 of this embodiment, the exhaust pipe 16 is connected to the detoxifying apparatus 20 via the pipe 17 provided with the opening and closing valve 18. Therefore, the reaction product 14 pressure-fed to the outside of the trap apparatus 5 through the pipe 16 is fed to the detoxifying apparatus 20 through the pipe 17. In the detoxifying apparatus 20, detoxifying treatment to the exhaust gas 16 and the reaction product 14 is performed and then the exhaust gas 16 and the reaction product 14 are discarded.

Incidentally, as the detoxifying apparatus 20, for example, an apparatus generally called “scrubber” can be used.

In the film-forming apparatus 1 of this embodiment having the above configuration, the reaction product 14 in the exhaust gas 6 is captured and collected in the trap section 5′, and is pressure-fed to the outside of the trap section 5′ using the inert gas 15, so that automatic discarding treatment can be performed. As a result, the risky reaction product 14 having the ignition quality can be discarded safely and simply without depending on a manual work under the atmosphere.

As shown in FIG. 1, the film-forming apparatus 1 of this embodiment can include a cleaning gas supply pipe 22 which supplies a cleaning gas 21 into the reaction chamber 2 at a top portion of the reaction chamber 2. The cleaning gas 21 is a gas which can react with the reaction product produced when a vapor-phase growth reaction occurs on the surface of the substrate in the reaction chamber 2 to decompose the same. As the cleaning gas 21, a chlorine trifluoride (ClF₃) gas can be used.

When the vapor-phase growth reaction occurs on the surface of the substrate in the reaction chamber 2, the reaction product is produced, but there is such a case that a portion of the reaction product is not exhausted from the reaction chamber 2 but adheres to an inner wall of the reaction chamber 2. Further, the reaction product contained in the exhaust gas 6 may adhere to an inner wall of the pipe 4. The cleaning gas 21 can decompose such a reaction product to gasify the same, thereby removing it from the reaction chamber 2 or the pipe 4.

In the film-forming apparatus 1 of this embodiment, it is preferred that, after film formation on the substrate using the reaction gas 7, cleaning using the cleaning gas 21 is performed. In the cleaning, after the substrate is conveyed out of the reaction chamber 2 after the film formation, the cleaning gas 21 is supplied to the reaction chamber 2 and it is exhausted using the exhaust mechanism 3. Thus, the reaction product which has adhered to the inner wall of the reaction chamber 2 and the inside of the pipe 4 can be removed by the cleaning gas 21, thereby cleaning the reaction chamber 2 and the pipe 4.

At this time, when the cleaning gas 21 is composed of a chlorine trifluoride gas or the like, it develops high reactivity with the reaction product formed from the reaction gas 7. Therefore, when the cleaning gas 21 is introduced into the place including a large amount of reaction product, it causes very severe reaction. The film-forming apparatus 1 of this embodiment has the trap apparatus 5 in the middle of the pipe 4, and there is such a possibility that a large amount of reaction product 14 has accumulated in the trap apparatus 5 after the film formation on the substrate.

Therefore, when the reaction product 14 which has accumulated in the trap section 5′ and the cleaning gas 21 come in contact with each other, there is a concern that severe decomposing reaction is caused, so that severe heat generation which may reach explosion occur.

Therefore, in the film-forming apparatus 1 of this embodiment, as shown in FIG. 1, a bypass pipe 25 for bypassing the trap section 5′ can be provided in the pipe 4 such that the cleaning gas 21 and the reaction product 14 which has accumulated in the trap section 5′ do not come in contact with each other.

The bypass pipe 25 is provided in the middle of the pipe 4 so as to bypass the trap section 5′, and an opening and closing valve 26 is provided in the middle of the bypass pipe 25. As described above, the opening and closing valve 9 is provided in the pipe 4a between the reaction chamber 2 and the exhaust gas introducing port 24. The opening and closing valve 26 and the opening and closing valve 9 function as a means for introducing the cleaning gas 21 from the reaction chamber 2 to the bypass pipe 25.

Accordingly, when cleaning is performed after the film formation on the substrate within the reaction chamber 2, the opening and closing valve 9 and the opening and closing valve 10 in the pipe 4 are closed, while the opening and closing valve 26 in the bypass pipe 25 is opened. As a result, after the cleaning gas 21 which has been supplied into the reaction chamber 2 cleans the inside of the reaction chamber 2, it bypasses the trap section 5′ through the bypass pipe 25. The cleaning gas 21 is exhausted by the exhaust mechanism 3 without being introduced into the trap section 5′, while cleaning the inside of the pipe 4.

Thus, in the film-forming apparatus 1, when cleaning is performed using the cleaning gas 21 for the reaction chamber 2 and the pipe 4, while a possibility that the reaction product 14 in the trap apparatus 5 and the cleaning gas 21 come in contact with each other is excluded, a safe cleaning work can be performed.

In the film-forming apparatus 1 of this embodiment, it is possible to provide a flow rate control valve 27 for controlling the flow rate of a gas at a position between the opening and closing valve 10 of the pipe 4 and the exhaust mechanism 3 and between the opening and closing valve 26 of the bypass pipe 25 and the exhaust mechanism 3. As the flow rate control valve 27, for example, a throttle valve can be used. By providing the flow rate control valve 27 in the pipe 4, the flow rate of the exhaust gas 6 or the cleaning gas 21 exhausted from the reaction chamber 2 can be controlled.

### Embodiment 2

The description of a film-forming apparatus according to the second embodiment of the present invention will be described using FIG. 2.

FIG. 2 is a schematic diagram for explaining a configuration of a main section of a film-forming apparatus of the second embodiment of the present invention.

A film-forming apparatus 100 of the second embodiment shown in FIG. 2 has the detoxifying apparatus 20 which can detoxify the exhaust gas 6 and the reaction product 14 to exhaust the same as the discarding system for the reaction product 14 like the film-forming apparatus 1. An inert gas supply mechanism 30 for supplying an inert gas into the pipe 17 is provided in the middle of the pipe 17 connecting the exhaust pipe 16 and the detoxifying apparatus 20. The film-forming apparatus 100 has a structure similar to that of the film-forming apparatus 1 shown in FIG. 1 except that the inert gas supply mechanism 30 for supplying an inert gas into the pipe 17 is provided in the middle of the pipe 17 in the second embodiment. Therefore, constituent elements similar to those in the film-forming apparatus 1 are attached with same reference numerals, and repetitive explanation thereof is omitted.

The inert gas supply mechanism 30 is composed of an inert gas supply cylinder 32 supplying an inert gas 34 into the pipe 17, a pipe 31 connecting the inert gas supply cylinder 32 and the pipe 17 to each other in a gas-piping fashion, and an opening and closing valve 33 arranged in the middle of the pipe 31. That is, in the inert gas supply mechanism 30, the inert gas supply cylinder 32 supplying the inert gas 34 is connected to the pipe 17 through the pipe 31 provided with the opening and closing valve 33.

It is preferred that a gas which does not react with the reaction product 14 within the trap section 5′ is selected and used as the inert gas 34. For example, besides a nitrogen gas, a helium (He) gas, a neon (Ne) gas, an argon (Ar) gas, or the like can be selected and used.

Therefore, in the film-forming apparatus 100, when an oily reaction product 14 has accumulated in the trap section 5′, the opening and closing valves 9 and 10 in the pipe 4a and the pipe 4b are closed, respectively. Thereafter, the inert gas 15 can be introduced into the inside of the trap apparatus 5 by opening the opening and closing valves 12 and 18, respectively. The reaction product 14 can be pressure-fed from the exhaust pipe 16 to the outside of the trap section 5′ by the supplying pressure of the inert gas 15 which has been supplied to the inside of the trap section 5′.

After a predetermined amount of reaction product 14 has been pressure-fed using the exhaust pipe 16, the opening and closing valve 18 is closed and the opening and closing valve 33 is then opened, so that the inert gas 34 is supplied to the inside of the pipe 17. Thereby, the pipe 17 can be prevented from being clogged with the reaction product 14. Further, the reaction product 14 within the pipe 17 can be fed to the detoxifying apparatus 20 efficiently, and the inside of the pipe 17 is purged by the inert gas 34, so that the reaction product 14 can be prevented from remaining in the inside of the pipe 17.

Incidentally, in the film-forming apparatus 100, it is possible to use one of the inert gas supply cylinder 13 which supplies the inert gas 15 into the inert gas supply pipe 11 and the inert gas supply cylinder 32 which supplies the inert gas 34 into the pipe 17 in a common use fashion. That is, for example, such a configuration is adopted that the pipe 31 is connected to the inert gas supply cylinder 13 by using only the inert gas supply cylinder 13. By adopting such a configuration, it is possible to supply the inert gas 15 from the inert gas supply cylinder 13 to feed the same to the inside of the pipe 17 without using the inert gas supply cylinder 32.

### Embodiment 3

Next, the description of a film-forming method according to the third embodiment of the present invention will be described.

The film-forming method of the third embodiment can be performed by using the film-forming apparatus 1 of the first embodiment and the film-forming apparatus 100 of the second embodiment. Therefore, while referring to FIG. 1 and FIG. 2 properly, explanation of the film-forming method of the third embodiment will be made.

For example, as shown in FIG. 1, the film-forming method of this embodiment includes a film-forming step of disposing a substrate (not shown) on which a film should be formed in the reaction chamber 2 of the film-forming apparatus 1, supplying the reaction gas 7 from the reaction gas supply pipe 8 to the reaction chamber 2, and performing film formation on the substrate according to a vapor-phase growth reaction.

At the film-forming step, as described later, the reaction product 14 contained in the exhaust gas 6 is collected in the trap section 5′. Therefore, a discarding step of discarding the reaction product 14 collected in the trap section 5′ can be provided after the film-forming step.

Further, a cleaning step of cleaning the film-forming apparatus 1 can be provided after the film-forming step.

At the film-forming step of the film-forming method of this embodiment, the reaction chamber 2 is maintained in a predetermined degree of vacuum or a normal pressure (0.1 MPa (760 Torr)) using the exhaust mechanism 3. The substrate is rotated within the reaction chamber 2 while being heated, and the reaction gas 7 which contains a raw material gas, a hydrogen gas which is a carrier gas, and the like and which are used for film formation of the vapor-phase growth film is supplied from the reaction gas supply pipe 8.

As the raw material gas contained in the reaction gas 7, there are monosilane, dichlorosilane, trichlorosilane, and the like.

By bringing the substrate (not shown) which has been heated and rotated in the reaction chamber 2 into contact with the reaction gas 7, a predetermined vapor-phase growth film is formed on the substrate.

At this film-forming step, during film formation of the predetermined vapor-phase growth film on the substrate and in a predetermined period after the film formation has been finished, the exhaust gas 6 is exhausted from the reaction chamber 2. The exhaust gas 6 contains the reaction product which has been produced when the reaction gas 7 reacts in a thermally-decomposing manner or reacts in a hydrogen-reducing manner to react on the surface of the substrate in a vapor-phase growing manner. Further, the exhaust gas 6 also contains an unreacted reaction gas 7 which is not involved in film formation of the vapor-phase growth film directly and whose components do not change chemically and it is exhausted from the reaction chamber 2 as a gas containing various components.

The exhaust gas 6 is cooled to flow from the reaction chamber 2 to the inside of the pipe 4 while the reaction product contained therein is being caused to adhere to the inner walls of the reaction chamber 2 and the pipe 4. When such a state is left as it is, the reaction chamber 2 and the pipe 4 are contaminated by the reaction product. Further, the oily reaction product gradually deposits on an inner face of the pipe 4.

When the sectional area of the space within the pipe 4 connecting the reaction chamber 2 and the exhaust mechanism 3 becomes small due to deposition of the reaction product, smooth exhaust of the exhaust gas 6 is blocked from the inside of the reaction chamber 2, so that the flow rate of the reaction gas 7 within the reaction chamber 2 may fluctuate. The fluctuation of the flow rate of the reaction gas 7 affects the pressure or the degree of vacuum in the reaction chamber 2, which results in destabilization of the film-forming conditions of the vapor-phase growth film. As a result, there is such a concern that the film thickness or the performance of the vapor-phase growth film to be formed on the substrate becomes uneven, so that lowering of the quality of the vapor-phase growth film is caused.

Therefore, in the film-forming method of this embodiment, the reaction product in the exhaust gas 6 which has been exhausted from the reaction chamber 2 is captured and collected in one place without causing clogging of the pipe 4 at the film-forming step. In the film-forming method of this embodiment, the trap apparatus 5 provided in the middle of the pipe 4 is utilized for capturing such a reaction product or the like, as shown in FIG. 1.

That is, in the film-forming method of this embodiment, the opening and closing valve 26 of the bypass pipe 25 used at the cleaning step described later is closed, and the opening and closing valve 9 in the pipe 4a and the opening and closing valve 10 in the pipe 4b are opened. Next, the flow rate of the gas flowing in the pipe 4 is controlled by using the flow rate control valve 27, so that the exhaust gas 6 from the reaction chamber 2 is guided to the trap apparatus 5. The exhaust gas 6 passes through the trap apparatus 5 to be exhausted by the exhaust mechanism 3.

At this time, it is preferred that by using the flow passage 28 for cooling water provided around the pipe 4a as the cooling apparatus, the exhaust gas 6 is cooled efficiently and the reaction product contained in the exhaust gas 6 is captured in the trap apparatus 5 efficiently. Such a configuration can be adopted that the trap section 5′ is cooled by providing a similar flow passage for cooling water about the trap section 5′.

As described above, in the film-forming method of this embodiment, by removing the reaction product from the exhaust gas 6 at the film-forming step, the reaction product can be prevented from depositing within the pipe 4. The film formation of the vapor-phase growth film on the substrate can be performed under the stable conditions, so that an epitaxial film with a high quality can be provided.

After the epitaxial film has been formed on the substrate, the substrate is conveyed out of the reaction chamber 2. Next, a new substrate is conveyed into the reaction chamber 2 and film formation of an epitaxial film is similarly conducted.

Here, in the film-forming method of this embodiment, it is possible to provide a discarding step for discarding the reaction product 14 which has accumulated in the trap apparatus 5 after the film-forming step of performing film formation on a substrate. That is, a situation of accumulation of the reaction product 14 in the trap section 5′ when a next substrate is conveyed into the reaction chamber 2 after the film formation of the epitaxial film has been finished on a substrate. As a result, when existence of at least a predetermined amount of reaction product 14 is confirmed, the discarding step can be provided. A discarding treatment of the reaction product 14 within the trap section 5′ can be performed before a substrate to be next subjected to the film-forming process is conveyed into the reaction chamber 2.

At the discarding step of the film-forming method of this embodiment, first of all, the opening and closing valves 9 and 10 in the pipe 4a and the pipe 4b of the trap apparatus 5 shown in FIG. 1 are closed, respectively. Next, the opening and closing valves 12 and 18 are opened, respectively. The inert gas 15 is introduced into the trap section 5′ from the inert gas supply pipe 11 connected to the inert gas supply cylinder 13 which is the inert gas supply section via the opening and closing valve 12 in a gas-piping fashion. It is preferred that a gas which does not react with the reaction product 14 within the trap section 5′ is selected and used as the inert gas 15. For example, besides a nitrogen gas, a helium (He) gas, a neon (Ne) gas, an argon (Ar) gas, or the like can be selected and used.

The reaction product 14 is pressure-fed from the exhaust pipe 16 to the outside of the trap section 5′ by the supplying pressure of the inert gas 15.

At this time, it is possible to set the internal capacity of the trap section 5′ to 3 liters to 10 liters, and it is preferred that the flow rate of the inert gas 15 is set to 1 liter/min. to 3 liters/min. and the supplying pressure is set to 100 kPa to 300 kPa. Incidentally, it is preferred that the supplying pressure of the inert gas 15 is adjusted according to the distance between the exhaust pipe 16 and a detoxifying apparatus 20 described later, and it is also preferred that a higher supplying pressure of the inert gas 15 is selected according to increase of the distance from the exhaust pipe 16 to the detoxifying apparatus 20.

In the film-forming method of this embodiment, the discarding treatment of the reaction product 14 which has been pressure-fed to the outside of the trap section 5′ can be performed at the discarding step by using the discarding system which can detoxify the exhaust gas 6 and the reaction product 14 to discard them.

The film-forming apparatus 1 shown in FIG. 1 has the detoxifying apparatus 20 as the discarding system. The detoxifying apparatus 20 is connected to the exhaust pipe 16 via the pipe 17 provided with the opening and closing valve 18. Therefore, in the film-forming method of this embodiment, the reaction product 14 which has been pressure-fed from the exhaust pipe 16 to the outside of the trap section 5′ can be fed to the detoxifying apparatus 20 via the exhaust pipe 17. In the detoxifying apparatus 20, a detoxifying process to the exhaust gas 6 and the reaction product 14 is performed and the discarding treatment can be then performed.

Incidentally, as the detoxifying apparatus 20, for example, an apparatus generally called “scrubber” can be used.

In the film-forming method of this embodiment, it is possible to use a sealing container that can be sealed and can discard the reaction product without exposing the reaction product to the atmosphere as the discarding system for the reaction product 14 in place of the detoxifying apparatus 20. It is possible to connect the sealing container to the pipe 17, receive the reaction product 14 pressure-fed from the trap section 5′ through the exhaust pipe 16 and discard the reaction product 14 safely without exposing the same to the atmosphere.

In the film-forming method of this embodiment, it is preferred that an inert gas is supplied to the inside of the pipe 17 such that the pipe 17 is not clogged by the reaction product 14 pressure-fed from the trap section 5′ through the exhaust pipe 16.

In the film-forming method of this embodiment, it is preferred that the inert gas supply mechanism 30 provided in the above-described film-forming apparatus 100 is utilized in order to perform supply of the inert gas into such a pipe 17. As shown in FIG. 2, at the discarding step, the opening and closing valves 9 and 10 in the pipe 4a and the pipe 4b are closed, respectively. Thereafter, the opening and closing valves 12 and 18 are opened, respectively, to introduce the inert gas 15 into the pipe 17. Next, the reaction product 14 is pressure-fed from the exhaust pipe 16 to the outside of the trap section 5′ by supplying pressure of the inert gas 15 which has been supplied to the inside of the trap apparatus 5.

Thereafter, a predetermined amount of reaction product 14 has been pressure-fed using the exhaust pipe 16, the opening and closing valve 18 is closed. Next, the inert gas 34 is supplied to the inside of the pipe 17 by opening the opening and closing valve 33 of the inert gas supply mechanism 30 of the film-forming apparatus 100. Thus, the pipe 17 can be prevented from being clogged by the reaction product 14. Further, the reaction product 14 within the pipe 17 can be fed to the detoxifying apparatus 20 efficiently, and the inside of the pipe 17 is purged by the inert gas 34, so that the reaction product 14 can be prevented from remaining in the pipe 17.

It is preferred that a gas which does not react with the reaction product 14 within the trap section 5′ is selected and used as the inert gas 34. For example, besides a nitrogen gas, a helium (He) gas, a neon (Ne) gas, an argon (Ar) gas, or the like can be selected and used.

Incidentally, in the film-forming method of this embodiment, it is possible to use only the inert gas supply cylinder 13 of the film-forming apparatus 100. That is, the pipe 31 of the inert gas supply mechanism 30 is connected to the inert gas supply cylinder 13. It is possible to supply the inert gas 15 from the inert gas supply cylinder 13 to feed the same to the inside of the pipe 17 instead of the inert gas 34 from the inert gas supply cylinder 32.

In the film-forming method of this embodiment according to the above method, at the film-forming step of performing film formation of the vapor-phase growth film on the substrate, the reaction product 14 in the exhaust gas 6 can be captured and collected in the trap section 5′ of the film-forming apparatus 1 or the film-forming apparatus 100. At the discarding step provided as necessary, the reaction product 14 can be discarded automatically using the discarding system such as, for example, the detoxifying apparatus 20 by pressure-feeding the reaction product 14 to the outside of the trap section 5′ using the inert gas 15. Further, by using the inert gas supply mechanism 30 of the film-forming apparatus 100, the reaction product 14 within the pipe 17 can be fed to the detoxifying apparatus 20 efficiently. As a result, a risky reaction product 14 having an ignition quality or the like can be discarded safely and simply without depending on a manual working under the atmosphere.

Further, in the film-forming method of this embodiment, it is possible to provide a cleaning step of cleaning the reaction chamber 2 and the pipe 4 connected thereto after the film-forming step.

At the film-forming step of the film-forming method of this embodiment, when the vapor-phase growth reaction on the surface of the substrate is performed within the reaction chamber 2, the reaction product is produced from the reaction gas 7. A portion of the reaction product 7 may adhere to the inner wall of the reaction chamber 2 without being exhausted from the reaction chamber 2. Further, the reaction product contained in the exhaust gas 6 may adhere to the inner wall of the pipe 4 connected to the reaction chamber 2.

Therefore, it is preferred that a cleaning step is provided after the substrate is conveyed out at the film-forming step. At the cleaning step, a cleaning gas 21 is supplied into the reaction chamber 2 from a cleaning gas supply pipe 22 provided at the top portion of the reaction chamber 2. The cleaning gas 21 is a gas which can react with the reaction product which has been produced when the vapor-phase growth reaction occurs on the surface of the substrate within the reaction chamber 2 to decompose the reaction product. As the cleaning gas 21, a chlorine trifluoride (ClF₃) gas can be used.

At the cleaning step, after the substrate after the film formation has been conveyed out, the reaction chamber 2 and the pipe 4 connected thereto are cleaned by supplying the cleaning gas 21 into the reaction chamber 2 and exhausting the cleaning gas 21 using the exhaust mechanism 3.

At this time, when the cleaning gas 21 is composed of a chlorine trifluoride gas or the like, it develops high reactivity with the reaction product formed from the reaction gas 7. Therefore, when a large amount of reaction product exists, the reaction product causes very severe reaction between the same and the cleaning gas 21.

There is such a case that a large amount of reaction product 14 has accumulated in the trap section 5′ after the film-forming step. Therefore, when the reaction product 14 which has accumulated in the trap section 5′ and the cleaning gas 21 come in contact with each other, there is such a concern that very severe decomposing reaction is caused, so that severe heat generation which may reach explosion occurs.

From the above, in the film-forming method of this embodiment, at the cleaning step, the cleaning is performed such that the cleaning gas 21 and the reaction product 14 which has accumulated in the trap section 5′ do not come in contact with each other. That is, the bypass 25 for bypassing the trap section 5′, which is provided in the pipe 4, is utilized, for example, using the film-forming apparatus 1 shown in FIG. 1.

In the film-forming method of this embodiment, a cleaning step is provided after the film-forming step. When the cleaning is performed, after the substrate is conveyed out, first, the opening and closing valve 9 and the opening and closing valve 10 of the pipe 4 are closed, while the opening and closing valve 26 of the bypass pipe 25 is opened.

Next, the cleaning gas 21 is introduced from the cleaning gas supply pipe 22 into the reaction chamber 2. After the inside of the reaction chamber 2 has been cleaned by the cleaning gas 21, the cleaning gas 21 is caused to pass through the bypass pipe 25 to bypass the trap section 5′. Thereafter, the cleaning gas 21 is exhausted by the exhaust mechanism 3, while cleaning the inside of the pipe 4, without being introduced into the trap section 5′.

Thus, in the film-forming method of this embodiment, at the cleaning step, even if the reaction product 14 has accumulated in the trap apparatus 5, such a risk does not occur that the reaction product 14 and the cleaning gas 21 come in contact with each other. In the film-forming method of this embodiment, the cleaning can be performed safely at the cleaning step.

Incidentally, in the film-forming method of this embodiment, it is possible to provide the above-described discarding step and cleaning step, respectively. In that case, as a timing of performing the cleaning step, it is possible to provide the cleaning step after the substrate has been conveyed out after the film-forming step and before the discarding step.

As described above, after the film-forming step, the cleaning work can be performed safely even in a state where the reaction product 14 has accumulated in the trap section 5′ by cleaning using the bypass pipe 25 of the pipe 4 without causing such a risk that the reaction product 14 and the cleaning gas 21 come in contact with each other. That is, the cleaning using the cleaning gas 21 can be performed irrespective of presence/absence of the reaction product in the trap section 5′.

Further, in the film-forming method of this embodiment, even after the substrate after the film formation has been conveyed out after the film-forming step, it is possible to provide the cleaning step after the above-described discarding step of the reaction product 14.

In that case, by the discarding step which has already been performed, removal of the reaction product 14 which has accumulated in the trap section 5′ may be performed. In that case, such a configuration can be adopted that the trap section 5′ is not bypassed by the cleaning gas 21 using the bypass pipe 25 at the cleaning step.

That is, at the cleaning step, it is possible to introduce the cleaning gas 21 into the trap section 5′. In that case, the opening and closing valves 9 and 10 in the pipes 4a and 4b are opened to introduce the cleaning gas 21 from the cleaning gas supply pipe 22 into the reaction chamber 2.

When a large amount of reaction product 14 does not exist but only a small amount thereof exists within the trap section 5′ after the discarding step, severe reaction due to the cleaning gas 21 does not occur within the trap section 5′. The inside of the trap section 5′ and the pipes 4a and 4b can be cleaned without causing a concern about severe heat generation or the like.

According to the present invention, the film-forming apparatus which can remove the reaction product simply and safely can be provided. The film-forming method which can remove the reaction product simply and safely can be provided.

The present invention is not limited to the embodiments described above and can be implemented in various modifications without departing from the spirit of the invention.

In addition to the above embodiments, an epitaxial growth system cited as the example of a film-forming apparatus for forming SIC film in the present invention is not limited to this. Reaction gas supplied into the reaction chamber for forming a film on its surface while heating the wafer, can also be applied to other apparatus like a CVD (Chemical Vapor Deposition) film-forming apparatus, and to form other epitaxial film.

The above description of the invention has not specified apparatus constructions, control methods, etc. which are not essential to the description of the invention, since any suitable apparatus constructions, control methods, etc, can be employed to implement the invention.

What is claimed is:

1. A film-forming apparatus comprising:
a reaction chamber having a reaction gas supply section which supplies a reaction gas, the reaction chamber configured to perform film formation on a substrate according to a vapor-phase growth reaction;
a trap section configured to capture a reaction product resulting from the vapor-phase growth reaction in an exhaust gas exhausted from the reaction chamber;
an exhaust mechanism configured to exhaust the exhaust gas except for the reaction product captured in the trap section to the outside; and
an inert gas supply section configured to supply an inert gas into the trap section in order to pressure-feed the reaction product captured to the outside of the trap section.

2. The film-forming apparatus according to claim 1, further comprising a discarding system configured to discard the reaction product which has been pressure-fed from the trap section.

3. The film-forming apparatus according to claim 1,
wherein the reaction chamber has a cleaning gas supply section supplying a cleaning gas for removing the reaction product, and
wherein the exhaust mechanism exhausts a cleaning exhaust gas containing the cleaning gas from the reaction chamber via a bypass pipe bypassing the trap section.

4. The film-forming apparatus according to claim 1, wherein a cooling water passage is provided around the trap section.

5. The film-forming apparatus according to claim 1, further comprising a cooling apparatus configured to cool an exhaust gas exhausted from the reaction chamber and feeding the exhaust gas to the trap section.

6. The film-forming apparatus according to claim 2, wherein
the inert gas supply section adjusts a supply pressure of the inert gas according to a distance between the trap section and the discarding system.

7. The film-forming apparatus according to claim 2, wherein
the discarding system is a sealing container which can be sealed and can discard the reaction product without exposing the reaction product to the atmosphere.

8. The film-forming apparatus according to claim 2, wherein
the discarding system is a detoxifying apparatus which can detoxify and discard the reaction product.

9. The film-forming apparatus according to claim 8, wherein
the detoxifying apparatus is a scrubber.

10. The film-forming apparatus according to claim 2, further comprising a second inert gas supply section configured to supply an inert gas between the trap section and the discarding system.

11. The film-forming apparatus according to claim 2, wherein
the inert gas supply section further supplies an inert gas between the trap section and the discarding system.

12. The film-forming apparatus according to claim 3, wherein the cleaning gas is a chlorine trifluoride gas.

13. The film-forming apparatus according to claim 3, further comprising a flow rate control section configured to control a flow rate of the exhaust gas or the cleaning exhaust gas each of which is exhausted by the exhaust mechanism.

14. The film-forming apparatus according to claim 13, wherein the flow rate control section is a throttle valve.

15. A film-forming method comprising:
providing a substrate in a reaction chamber and supplying a reaction gas into the reaction chamber to perform film formation on the substrate according to a vapor-phase growth reaction;
introducing an exhaust gas exhausted from the reaction chamber into a trap section, capturing a reaction product contained in the exhaust gas, and exhausting the exhaust gas except for the captured reaction product; and
supplying an inert gas into the trap section to pressure-feed the reaction product captured to the outside of the trap section.

16. The film-forming method according to claim 15, further comprising: supplying a cleaning gas into the reaction chamber for cleaning the reaction product, and exhausting a cleaning exhaust gas containing the cleaning gas through a bypass pipe bypassing the trap section.

17. The film-forming method according to claim 16, wherein the cleaning performed by supplying the cleaning gas into the reaction chamber is performed after a vapor-phase growth reaction has been performed and before the reaction product captured by the trap section is pressure-fed to the outside of the trap section.

18. The film-forming method according to claim 16, wherein the cleaning performed by supplying the cleaning gas into the reaction chamber is performed after the reaction product captured by the trap section has been pressure-fed to the outside of the trap section.
